(19) United States
(12) Patent Application Publication
(10) Pub. No.: US 2025/0234661 A1
(43) Pub. Date: Jul. 17, 2025

(54) IMAGE SENSOR AND METHOD OF FABRICATING THE SAME

(71) Applicant: SAMSUNG ELECTRONICS CO., LTD., Suwon-si (KR)

(72) Inventors: TAESUNG LEE, Suwon-si (KR); Junghyun KIM, Suwon-si (KR); HYUNGEUN YOO, Suwon-s (KR); YUN KI LEE, Suwon-si (KR)

(73) Assignee: SAMSUNG ELECTRONICS CO., LTD., Suwon-si (KR)

(21) Appl. No.: 19/024,544

(22) Filed: Jan. 16, 2025

(30) Foreign Application Priority Data
Jan. 16, 2024 (KR) 10-2024-0007001

(51) Int. Cl. H10F 39/00; H10F 39/18

(52) U.S. Cl. CPC H10F 39/8053; H10F 39/182; H10F 39/8063; H10F 39/807

(57) ABSTRACT

An image sensor including color filter groups and microlenses is provided. The color filter groups may include first, second and third color filter groups. The first color filter group includes a first first wavelength band filter and a second first wavelength band filter. The third color filter group includes a first third wavelength band filter. A first microlens on the first first wavelength band filter has a different size than a second microlens on the second first wavelength band filter. A diameter of the first microlens on the first first wavelength band filter is larger than a diameter of a third microlens on the first third wavelength band filter. The microlenses overlap at least four of the color filters.

### CROSS-REFERENCE TO RELATED APPLICATIONS

This U.S. non-provisional patent application is based on and claims priority under 35 U.S.C. § 119 to Korean Patent Application No. 10-2024-0007001, filed on Jan. 16, 2024, in the Korean Intellectual Property Office, the entire contents of which are hereby incorporated by reference.

### BACKGROUND

The disclosure relates to an image sensor and a method of fabricating the same, and in particular, to a complementary metal oxide semiconductor (CMOS) image sensor and a method of fabricating the same.

An image sensor is a semiconductor device that converts an optical image into electrical signals. With the recent development in image capturing technologies, there is an increasing demand for high-performance image sensors in a variety of applications such as digital cameras, camcorders, personal communication systems (e.g., smart phones, tablets, wearable devices, laptops, etc.), gaming machines, security cameras, micro-cameras for medical applications, and/or robots. The image sensor may be classified into two types: a charge coupled device (CCD) type and a complementary metal-oxide-semiconductor (CMOS) type. In general, the CMOS-type image sensor is called “CIS”. The CIS device includes a plurality of two-dimensionally-arranged pixels. Each of the pixels includes a photodiode (PD) that coverts incident light into an electrical signal. The pixels are defined by a deep isolation pattern provided between adjacent pixels. A plurality of devices or components in each pixel are separated from each other by a device isolation pattern.

### SUMMARY

Provided is an image sensor configured to minimize a signal difference between pixels sharing the same color filter, and a method of fabricating the same.

Further provided is a highly-sensitive image sensor with increased light-reflection efficiency and a method of fabricating the same.

Further provided is an image sensor, which can be easily integrated, and a method of fabricating the same.

According to an aspect of the disclosure, there is provided an image sensor, including: a semiconductor substrate including a pixel array region, which has a first pixel region, a second pixel region surrounding the first pixel region, and a third pixel region surrounding the second pixel region; a plurality of color filter groups provided on the pixel array region, each of the plurality of color filter groups including a plurality of color filters; and a plurality of microlenses provided on the plurality of color filter groups, respectively, wherein the plurality of color filter groups includes a first color filter group on the first pixel region, a second color filter group on the second pixel region, and a third color filter group on the third pixel region, wherein the first color filter group includes a first first wavelength band filter configured to pass light of a first wavelength band and a second first wavelength band filter configured to pass light of a second wavelength band different from the first wavelength band, wherein the third color filter group includes a first third wavelength band filter configured to pass light having a wavelength within the first wavelength band, wherein, in the first color filter group, a first diameter of a first microlens, among the plurality of microlenses, on the first first wavelength band filter is different from a second diameter of a second microlens, among the plurality of microlenses, on the second first wavelength band filter, wherein the first diameter of the first microlens on the first first wavelength band filter of the first color filter group is larger than a third diameter of a third microlens, among the plurality of microlenses, on the first third wavelength band filter of the third color filter group, and wherein the plurality of microlenses are overlaps at least four of the plurality of color filters.

According to another aspect of the disclosure, there is provided an image sensor, including: a semiconductor substrate including a pixel array region, which has a first pixel region, a second pixel region surrounding the first pixel region, and a third pixel region surrounding the second pixel region; a plurality of color filter groups provided on the pixel array region, each of the plurality of color filter groups including a plurality of color filters; a plurality of photoelectric conversion parts corresponding to the color filters, respectively; and a plurality of microlenses provided on the plurality of color filter groups, respectively, wherein each of the plurality of microlenses corresponds to four of the plurality of photoelectric conversion parts, wherein the plurality of color filter groups includes a first color filter group on the first pixel region, a second color filter group on the second pixel region, and a third color filter group on the third pixel region, wherein each of the first color filter group, the second color filter group, and the third color filter group includes a first wavelength band filter, a second wavelength band filter, and a third wavelength band filter, which are configured to pass light having wavelengths in different wavelength bands, wherein a diameter of a first microlens, among the plurality of microlenses, on the first wavelength band filter of the first color filter group is larger than a diameter of a second microlens, among the plurality of microlenses, on the first wavelength band filter of the third color filter group, and wherein in the third color filter group, a diameter of a third microlens, among the plurality of microlenses, corresponding to the first wavelength band filter is different from a diameter of a fourth microlens, among the plurality of microlenses, corresponding to the second wavelength band filter.

According to an aspect of the disclosure, there is provided an image sensor, including: a semiconductor substrate including a light-receiving region, a light-blocking region, and a pad region, the semiconductor substrate having a first surface and a second surface, which are opposite to each other; a deep device isolation pattern provided in the light-receiving region and the light-blocking region of the semiconductor substrate to define pixel regions; a plurality of photoelectric conversion regions provided in the light-receiving region and the light-blocking region of the semiconductor substrate; a plurality of color filter groups provided on the second surface, each of the color filter groups including a first color filter, a second color filter, a third color filter and a fourth color filter arranged in two rows and two columns; a transfer gate on the first surface; a pixel circuit layer on the first surface; and a plurality of microlenses provided on the plurality of color filter groups, respectively, wherein one of the microlenses overlaps with the first color filter, the second color filter, the third color filter and the fourth color filter, wherein the light-receiving region includes: a first pixel region, a second pixel region surrounding the first pixel region; and a third pixel region surrounding the second pixel region, wherein the plurality of color filter groups comprises: a first color filter group on the first pixel region; a second color filter group on the second pixel region; and a third color filter group on the third pixel region, wherein the first color filter group includes a first first wavelength band filter and a second first wavelength band filter, which are configured to pass light in different wavelength bands from each other, wherein the third color filter group includes a first third wavelength band filter, which is configured to pass light in a same wavelength band as the first first wavelength band filter, wherein, in the first color filter group, a diameter of a first microlens, among the plurality of microlenses, on the first first wavelength band filter is larger than a diameter of a second microlens, among the plurality of microlenses, on the second first wavelength band filter, and wherein a plurality of third microlenses on the first first wavelength band filter of the first color filter group, among the plurality of microlenses, have diameters that are larger than a plurality of fourth microlenses on the first third wavelength band filter of the third color filter group, among the plurality of microlenses.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram schematically illustrating an image sensor according to an embodiment of the inventive concept.

FIGS. 2A and 2B are circuit diagrams illustrating a unit pixel of an image sensor according to an embodiment of the inventive concept.

FIG. 3A is a plan view illustrating an image sensor according to an embodiment of the inventive concept.

FIG. 3B is an enlarged view illustrating a light-receiving region of FIG. 3A.

FIG. 3C is a plan view illustrating a region X of FIG. 3B.

FIG. 3D is a plan view illustrating a region Y of FIG. 3B.

FIG. 3E is a plan view illustrating a region Z of FIG. 3B.

FIG. 4 is a sectional view taken along a line A-A′ of FIG. 3B to illustrate an image sensor according to an embodiment of the inventive concept.

FIG. 5 is a sectional view taken along a line B-B′ of FIG. 3B to illustrate an image sensor according to an embodiment of the inventive concept.

FIG. 6 is a sectional view taken along a line C-C′ of FIG. 3B to illustrate an image sensor according to an embodiment of the inventive concept.

FIG. 7 is a sectional view taken along the line A-A′ of FIG. 3B to illustrate an image sensor according to another embodiment of the inventive concept.

FIG. 8 is a sectional view taken along the line B-B′ of FIG. 3B to illustrate an image sensor according to another embodiment of the inventive concept.

FIG. 9 is a sectional view taken along the line C-C′ of FIG. 3B to illustrate an image sensor according to another embodiment of the inventive concept.

### DETAILED DESCRIPTION

Example embodiments of the inventive concepts will now be described more fully with reference to the accompanying drawings, in which example embodiments are shown.

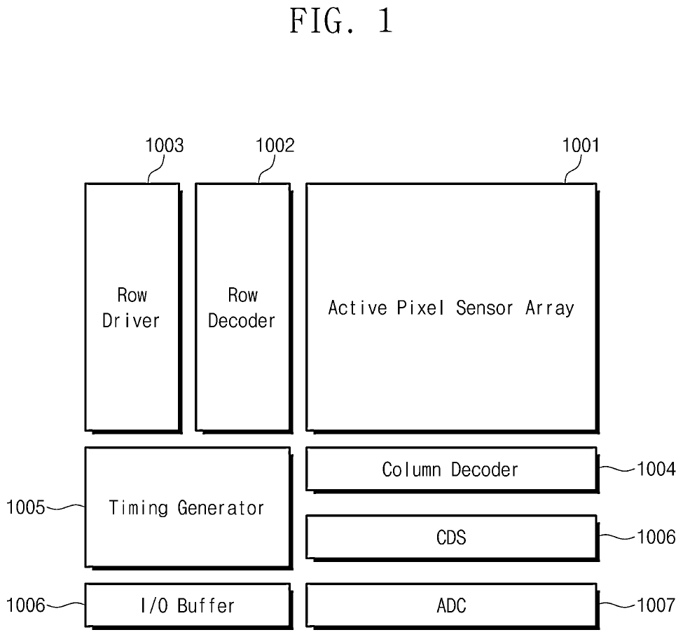

FIG. 1 is a block diagram schematically illustrating an image sensor according to an embodiment of the inventive concept.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output (I/O) buffer 1008.

The active pixel sensor array 1001 may include a plurality of unit pixels that are arranged two-dimensionally and are used to convert optical signals to electrical signals. The active pixel sensor array 1001 may be driven by a plurality of driving signals, such as a pixel selection signal, a reset signal, and a charge transfer signal, which are transmitted from the row driver 1003. In addition, the converted electrical signals may be provided to the CDS 1006.

The row driver 1003 may be configured to provide the driving signals, which are used to drive the plurality of unit pixels, to the active pixel sensor array 1001, based on the result decoded by the row decoder 1002. In the case where the unit pixels are arranged in a matrix shape (i.e., in rows and columns), the driving signals may be provided to respective rows.

The timing generator 1005 may be configured to provide timing and control signals to the row decoder 1002 and the column decoder 1004.

The CDS 1006 may be configured to receive the electric signals generated in the active pixel sensor array 1 and to perform a holding and sampling operation on the received electric signals. For example, the CDS 1006 may perform a double sampling operation on a specific noise level and a signal level of the electric signal and may output a difference level corresponding to a difference between the noise and signal levels.

The ADC 1007 may be configured to convert analog signals, which correspond to the level output from the CDS 1006, into digital signals, and then to output the converted digital signals to the I/O buffer 1008.

The I/O buffer 1008 may be configured to latch the digital signal and to sequentially output the latched digital signals to an image signal processing unit, based on the result decoded by the column decoder 1004.

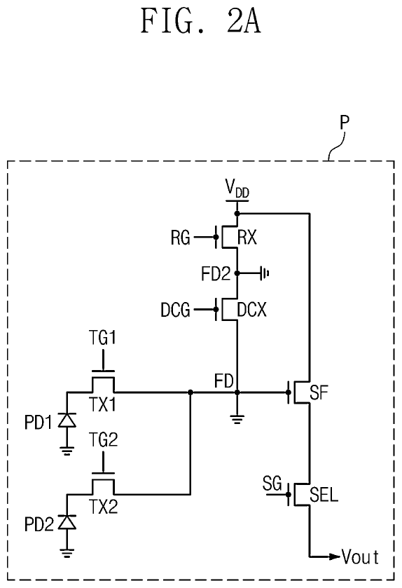

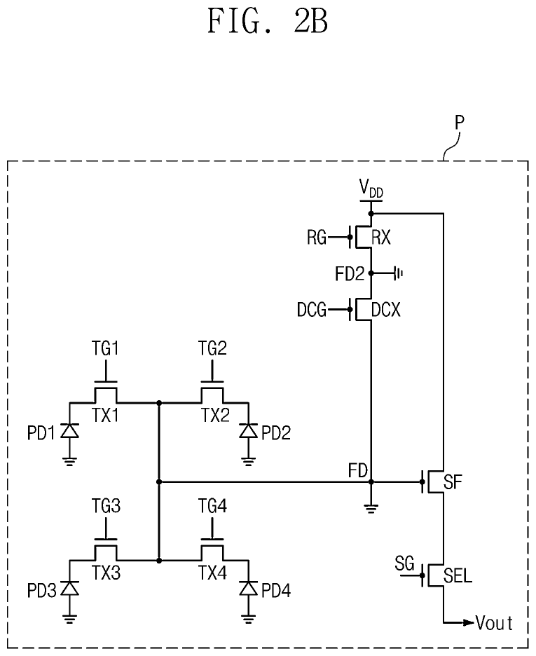

FIGS. 2A and 2B are circuit diagrams illustrating a unit pixel of an image sensor according to an embodiment of the inventive concept.

Referring to FIG. 2A, a unit pixel P may include first and second photoelectric conversion devices PD1 and PD2, first and second transfer transistors TX1 and TX2, and four pixel transistors. For example, each of the four pixel transistors may correspond to a reset transistor RX, a source follower transistor SF, a selection transistor SEL, and a dual conversion gain transistor DCX, but the inventive concept is not limited to this example. That is, the pixel transistors in in each unit pixel P may be provided in various manners.

The first and second photoelectric conversion devices PD1 and PD2 may be configured to generate electric charges in response to an incident light, and in this case, the generated electric charges may be accumulated in the first and second photoelectric conversion devices PD1 and PD2. For example, the first and second photoelectric conversion devices PD1 and PD2 may be photodiodes, phototransistors, photogates, or pinned photo diodes (PPDs).

The first and second transfer transistors TX1 and TX2 may be configured to transfer the electric charges, which are accumulated in the first and second photoelectric conversion devices PD1 and PD2, to a floating diffusion region FD. The first and second transfer transistors TX1 and TX2 may be controlled by signals that are applied to first and second transfer gate electrodes TG1 and TG2. The first and second transfer transistors TX1 and TX2 may share the floating diffusion region FD, but the inventive concept is not limited to this example. That is, the first and second transfer transistors TX1 and TX2 may be connected to different ones of the floating diffusion regions FD, respectively.

The floating diffusion region FD may be configured to receive the electric charges, which are accumulated in the first or second photoelectric conversion device PD1 or PD2, and to cumulatively store the electric charges. The source follower transistor SF may be controlled by an amount of the photocharges stored in the floating diffusion region FD.

The reset transistor RX may periodically initialize electric charges, which are accumulated in the floating diffusion region FD, based on a reset signal applied to a reset gate electrode RG. In detail, a drain terminal of the reset transistor RX may be connected to the dual conversion gain transistor DCX, and a source terminal may be connected to a pixel power voltage VDD. In an example case in which the reset transistor RX and the dual conversion gain transistor DCX are turned on, the pixel power voltage VDD may be transmitted to the floating diffusion region FD. Accordingly, the electric charges accumulated in the floating diffusion region FD may be discharged, and thus, the floating diffusion region FD may be initialized.

The dual conversion gain transistor DCX may be provided between and connected to the floating diffusion region FD and the reset transistor RX. The dual conversion gain transistor DCX may control a conversion gain by changing the capacitance of the floating diffusion region FD in response to a dual conversion gain control signal. That is, the dual conversion gain transistor DCX may be configured to achieve at least two different values of the conversion gain. Thus, the dual conversion gain transistor DCX may be turned on in a high brightness mode and may be turned off in a low brightness mode.

The source follower transistor SF may be a source follower buffer amplifier that is configured to produce a source-drain current in proportion to the amount of electric charges input from the first floating diffusion region FD1 to a gate electrode of the source follower transistor SF. The source follower transistor SF may amplify a variation in electric potential of the floating diffusion region FD and may output the amplified signal to an output line Vₒᵤₜ through the selection transistor SEL. A source terminal of the source follower transistor SF may be connected to the pixel power voltage V_{DD}, and a drain terminal of the source follower transistor SF may be connected to a source terminal of the selection transistor SEL.

The selection transistor SEL may be used to select a specific row of the unit pixels P to be read out during a read operation. In an example case in which the selection transistor SEL is turned on by a selection signal applied to a selection gate electrode SG, an electrical signal, which is output to a drain electrode of the source follower transistor SF, may be output to the output line Vₒᵤₜ.

Referring to FIG. 2B, the unit pixel P may include first to fourth photoelectric conversion devices PD1, PD2, PD3, and PD4, first to fourth transfer transistors TX1, TX2, TX3, and TX4, and four pixel transistors.

The first to fourth transfer transistors TX1, TX2, TX3, and TX4 may be configured to share the floating diffusion region FD. The first to fourth transfer transistors TX1, TX2, TX3, and TX4 may be controlled by signals applied to first to fourth transfer gate electrodes TG1, TG2, TG3, and TG4.

The four pixel transistors may correspond to the reset transistor RX, the source follower transistor SF, the selection transistor SEL, and the dual conversion gain transistor DCX described with reference to FIG. 2A.

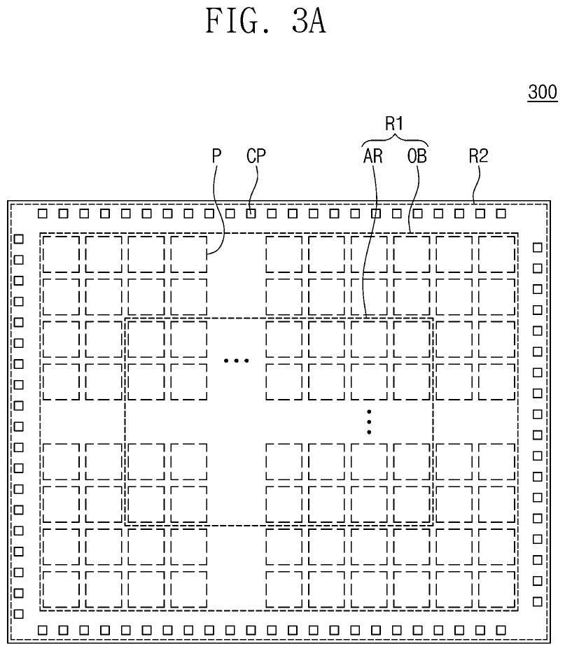

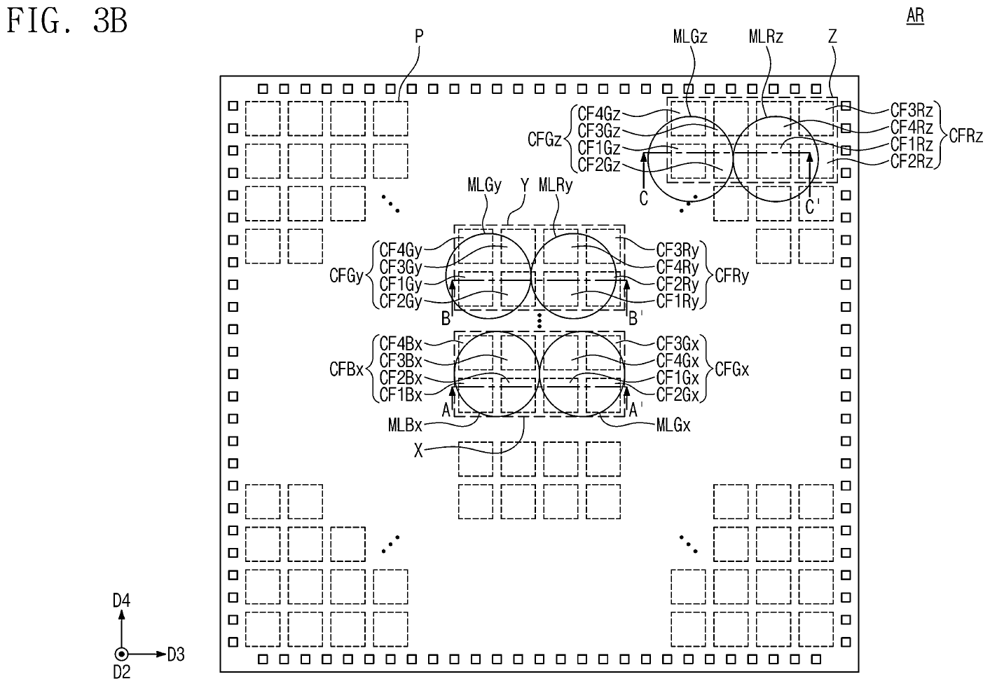

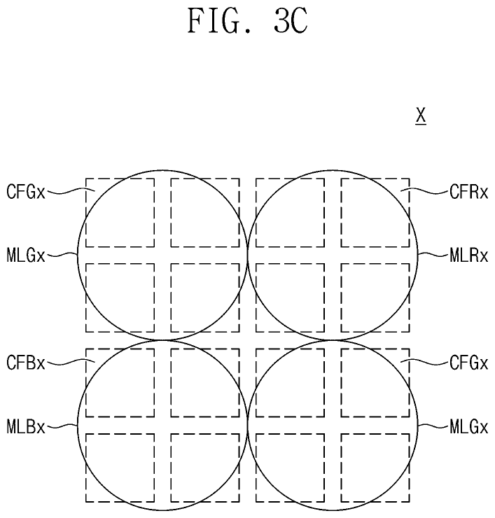

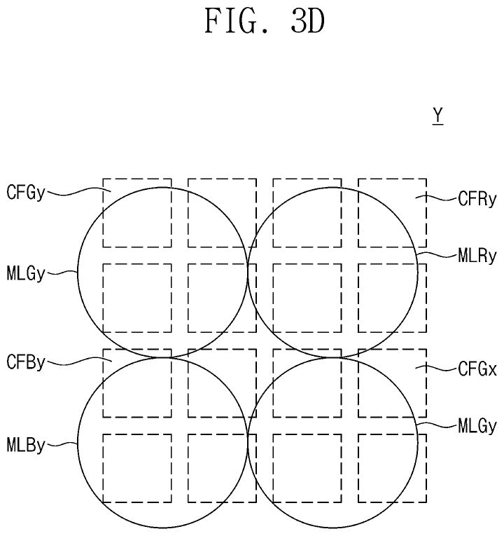

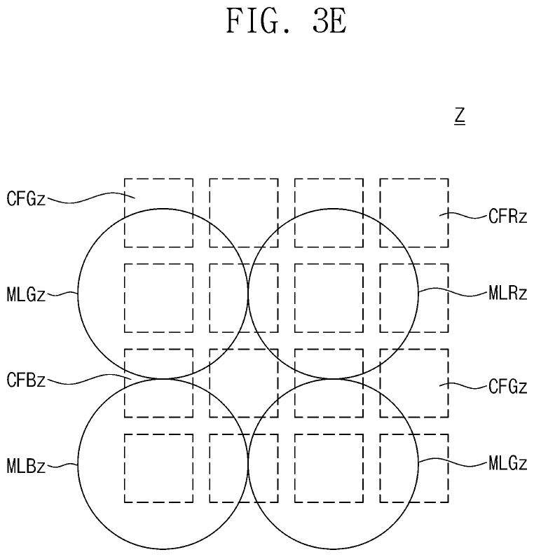

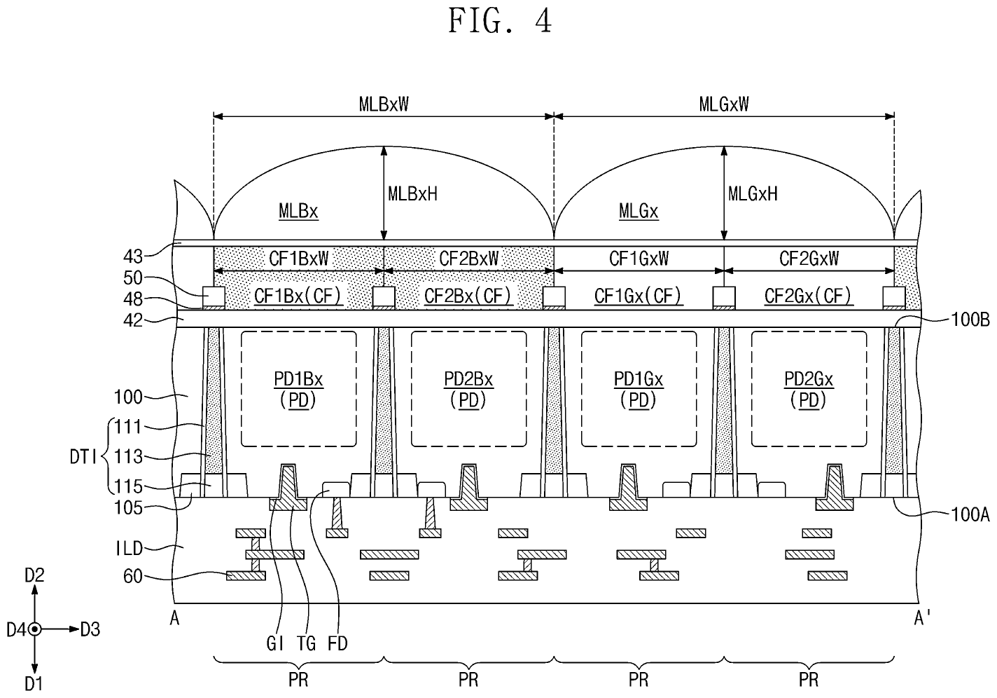

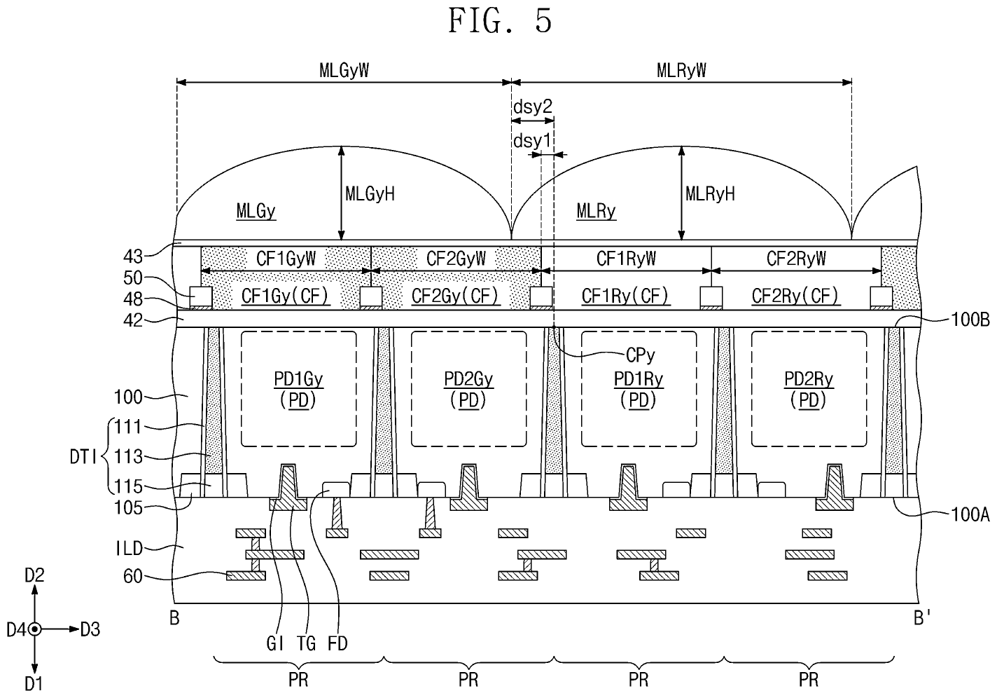

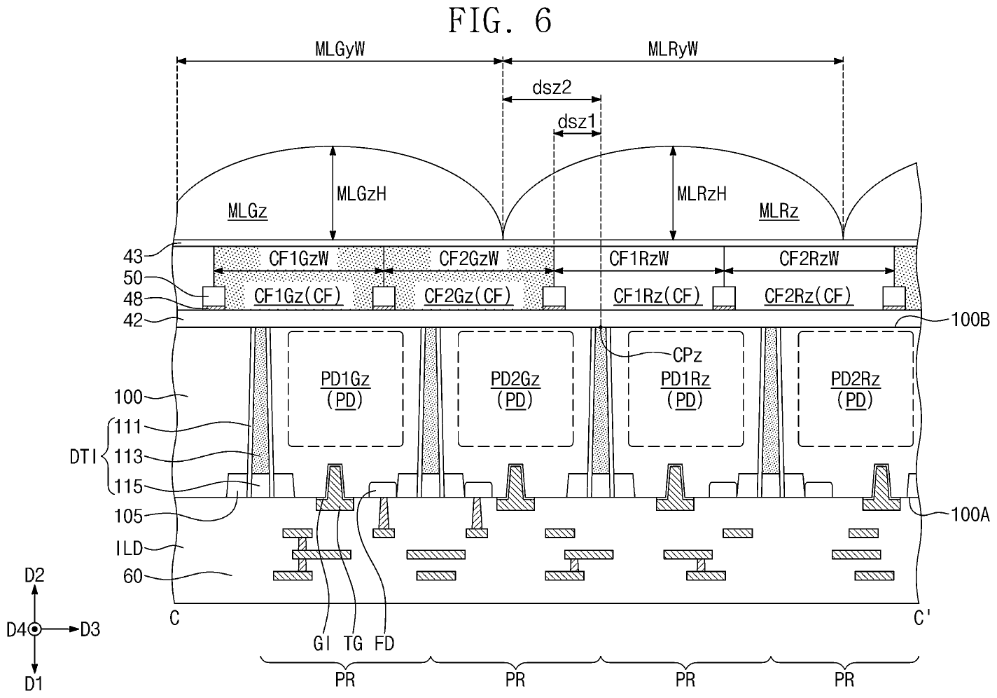

FIG. 3A is a plan view illustrating an image sensor 300 according to an embodiment of the inventive concept. FIG. 3B is an enlarged view illustrating a light-receiving region of FIG. 3A. FIG. 3C is a plan view illustrating a region X of FIG. 3B. FIG. 3D is a plan view illustrating a region Y of FIG. 3B. FIG. 3E is a plan view illustrating a region Z of FIG. 3B. FIG. 4 is a sectional view taken along a line A-A′ of FIG. 3B to illustrate an image sensor according to an embodiment of the inventive concept. FIG. 5 is a sectional view taken along a line B-B′ of FIG. 3B to illustrate an image sensor according to an embodiment of the inventive concept. FIG. 6 is a sectional view taken along a line C-C′ of FIG. 3B to illustrate an image sensor according to an embodiment of the inventive concept.

Referring to FIGS. 3A and 3B, the image sensor 300 may include a pixel array region R1 and a pad region R2.

The pixel array region R1 may include a plurality of pixels P, which are two-dimensionally arranged in a third direction D3 and a fourth direction D4 crossing each other. Each of the pixels P may include a photoelectric conversion device and at least one readout device. Each of the pixels P of the pixel array region R1 may be configured to output electrical signals, which are generated based on incident light. For example, in response to incident light on a pixel P, the pixel P may generate and output an electrical signal.

The pixel array region R1 may include a light-receiving region AR and a light-blocking region OB. In a plan view, the light-blocking region OB may be configured to surround the light-receiving region AR. In an example, the light-blocking region OB may be provided adjacent to the light-receiving region AR. In other words, in a plan view, the light-blocking region OB may be provided to surround the light-receiving region AR in four different directions (e.g., up, down, left, and rights directions). In an example, the light-blocking region OB may be provided to enclose the light-receiving region AR. In an embodiment, reference pixels P may be provided in the light-blocking region OB. For example, the reference pixels P may be pixels on which light is not incident. In this case, by comparing a charge amount, which is obtained from the unit pixel P in the light-receiving region AR, with a reference amount of charges generated in the reference pixels P, it may be possible to calculate a magnitude of an electrical signal generated by the unit pixel P.

Referring to FIG. 3B, the pixel array region R1 may include a center pixel region X, which is provided with a plurality of pixels in the light-receiving region AR, a middle pixel region Y, which is provided to surround the center pixel region X in a plan view, and an edge pixel region Z, which is provided to surround the middle pixel region Y in a plan view. The middle pixel region Y may be provided to surround the center pixel region X in vertical and horizontal directions in a plan view. The edge pixel region Z may be provided to surround the middle pixel region Y in vertical and horizontal directions in a plan view. For example, the middle pixel region Y may be provided adjacent to the center pixel region X in the vertical and the horizontal directions in a plan view, and the edge pixel region Z may be provided to be adjacent to the middle pixel region Y in the vertical and the horizontal directions in a plan view. Here, light may be incident into the edge pixel region Z, the middle pixel region Y, and the center pixel region X at different angles. According to an embodiment, the center pixel region X may be referred to as a first pixel region X, the middle pixel region Y may be referred to as a second pixel region Y, and the edge pixel region Z may be referred to as a third pixel region Z. Although, three pixel regions (X, Y and Z) are illustrated in FIG. 3B, the disclosure is not limited thereto, and as such, the number of regions may be different than three. For example, the pixel array region R1 may include a fourth pixel region between the second pixel region Y and the third pixel region Z.

According to an embodiment, color filters and microlenses may be provided on the pixel array region R1.

For example, the color filters may be provided on the pixels P of the pixel array region R1. For example, the color filters may be provided on the pixel array region R1 to respectively cover the pixels P. The color filters may be arranged in n rows and n columns to form a plurality of color filter groups.

The color filter groups may include a center color filter group on the center pixel region X, a middle color filter group on the middle pixel region Y, and an edge color filter group on the edge pixel region Z. According to an embodiment, the center color filter group may be referred to as a first color filter group, the middle color filter group may be referred to as a second color filter group, and the edge color filter group may be referred to as a third color filter group.

The color filters may include red color filters, green color filters, and blue color filters. The red, green, and blue color filters may be configured to selectively pass the incident light.

The microlenses may be configured to condense the incident light that is incident on the pixels P from the outside. In a plan view, the microlenses may be two-dimensionally arranged in the third direction D3 and the fourth direction D4, which are not parallel to each other.

In an embodiment, each of the microlenses may be provided to on one of the color filter groups. For example, each of the microlenses may be provided to cover one of the color filter groups. In an embodiment, each of the microlens may cover a color filter group, in which the color filters are arranged in two rows and two columns. The color filters and the microlenses will be described in more detail with reference to FIGS. 4 to 9.

According to an embodiment, the image sensor 300 may include a substrate 100. For example, the substrate 100 may be a single-crystalline silicon wafer, a silicon epitaxial layer, or a silicon-on-insulator (SOI) substrate. In an embodiment, the substrate 100 may be doped with impurities of a first conductivity type. For example, the first conductivity type may be p-type. However, the disclosure is not limited thereto, and as such, the first conductivity type may be n-type. The substrate 100 may include a first surface 100A and a second surface 100B, which are opposite to each other. An outward direction, which is normal to the first surface 100A, may be defined as a first direction D1, and an outward direction, which is normal to the second surface 100B, may be defined as a second direction D2.

In each of pixel regions PR, a device isolation layer 105 may be provided adjacent to the first surface 100A of the substrate 100. The device isolation layer 105 may be provided in a device isolation trench, which is formed by recessing the first surface 100A of the substrate 100. The device isolation layer 105 may include an insulating material. The device isolation layer 105 may define an active portion in the first surface 100A of the substrate 100. For example, the device isolation layer 105 may define a first active portion and a second active portion in the substrate 100. The first and second active portions may be spaced apart from each other in each of the pixel regions PR and may have different sizes from each other.

A deep device isolation pattern DTI may be provided in the substrate 100. The pixel regions may be separated from each other by the deep device isolation pattern DTI. For example, the deep device isolation pattern DTI may be provided between the pixel regions P and may penetrate the substrate 100 in the second direction D2.

The deep device isolation pattern DTI may include a liner insulating pattern 111, a semiconductor pattern 113, and a capping insulating pattern 115.

The semiconductor pattern 113 may be provided to penetrate at least a portion of the substrate 100 in the first direction D1. The liner insulating pattern 111 may be provided between the semiconductor pattern 113 and the substrate 100. The semiconductor pattern 113 may be provided on the capping insulating pattern 115.

A bottom surface of the semiconductor pattern 113 may be located at substantially the same level as the second surface 100B of the substrate 100. A top surface of the semiconductor pattern 113 may be in direct contact with a bottom surface of the capping insulating pattern 115. An air gap or void may be present in the semiconductor pattern 113. In an embodiment, the semiconductor pattern 113 may be formed of or include polysilicon.

The bottom surface of the capping insulating pattern 115 may be located at a level that is lower than and substantially equal to a bottom surface of the device isolation layer 105. The bottom surface of the capping insulating pattern 115 may have a rounded shape. A top surface of the capping insulating pattern 115 may be located at substantially the same level as a bottom surface of the device isolation layer 105 (i.e., the first surface 100A of the substrate 100). The liner insulating pattern 111 may be provided on a side surface of the semiconductor pattern 113 and a side surface of the capping insulating pattern 115. For example, the liner insulating pattern 111 may cover a side surface of the semiconductor pattern 113 and a side surface of the capping insulating pattern 115 conformally (i.e., to substantially uniform thickness). In an embodiment, the liner insulating pattern 111 and the capping insulating pattern 115 may be formed of or include at least one of silicon oxide, silicon oxynitride, or silicon nitride. However, the disclosure is not limited thereto, and as such, the liner insulating pattern 111 and the capping insulating pattern 115 may include another material.

The deep device isolation pattern DTI may be provided in a trench, which is extended from the first surface 100A toward the second surface 100B. In a plan view, the deep device isolation pattern DTI may have a mesh or net shape, which is formed by line-shaped patterns extended in the third and fourth directions D3 and D4.

The deep device isolation pattern DTI may be extended from the first surface 100A into the substrate 100 and may be interposed between the pixel regions PR. The deep device isolation pattern DTI may define a plurality of photoelectric conversion parts. The deep device isolation pattern DTI may be provided to penetrate the substrate 100 in a direction from the first surface 100A toward the second surface 100B. The deep device isolation pattern DTI may be provided to penetrate a portion of the device isolation layer 105.

The deep device isolation pattern DTI may have lower width at a level of the first surface 100A of the substrate 100 and may have upper width at a level of the second surface 100B of the substrate 100. The upper width may be smaller than the lower width. For example, the width of the deep device isolation pattern DTI may gradually decrease as a distance from the first surface 100A of the substrate 100 increases in a direction toward the second surface 100B. The deep device isolation pattern DTI may have a length in the second direction D2. The length of the deep device isolation pattern DTI may be substantially equal to a vertical thickness of the substrate 100.

Photoelectric conversion regions PD may be provided in each of the pixel regions PR of the substrate 100. The photoelectric conversion regions PD may generate photocharges in proportion to an intensity of an incident light. The photoelectric conversion regions PD may be formed by injecting impurities, which are of a second conductivity type different from the substrate 100, into the substrate 100. The photoelectric conversion region PD of the second conductivity type and the substrate 100 of the first conductivity type may form a PN junction serving as a photodiode. In an embodiment, each of the photoelectric conversion regions PD may be provided to have a difference in doping concentration between portions adjacent to the first and second surfaces 100A and 100B, thereby having a non-vanishing gradient in potential between the first and second surfaces 100A and 100B of the semiconductor substrate 100. For example, the photoelectric conversion regions PD may include a plurality of impurity regions which are vertically stacked.

In each pixel region PX, a transfer gate TG, a gate insulating film and a floating diffusion region FD may be provided. For example, the transfer gate TD may be provided on the first surface 100A of the substrate 100. In an embodiment, a portion of the transfer gate TG may be buried in the substrate 100. The transfer gate TG may be of a vertical type. In an embodiment, the transfer gate TG may be a planar or flat-shaped pattern, which is provided on the first surface 100A of the substrate 100.

The gate insulating pattern GI may be interposed between the transfer gate TG and the substrate 100. The floating diffusion region FD may be provided in a portion of the substrate 100 adjacent to a side of the transfer gate TG. In an embodiment, the floating diffusion region FD may be doped with impurities of the second conductivity type.

The floating diffusion region FD may be provided in a portion of a first active portion located at a side of the transfer gate TG. The floating diffusion region FD may be formed by injecting impurities, which have a conductivity type different from the substrate 100, into the substrate 100. For example, the floating diffusion region FD may be an impurity region of the second conductivity type.

In an embodiment, light may be incident into the substrate 100 through the second surface 100B of the substrate 100. Electron-hole pairs may be generated in the PN junction by the incident light. The electrons, which are generated by this process, may be transferred to the photoelectric conversion part PD. The electrons may be transferred to the floating diffusion region FD by applying a voltage to the transfer gate TG.

An interlayer insulating layer ILD may be provided on the first surface 100A of the substrate 100. For example, the interlayer insulating layer ILD may be provided to cover the first surface 100A. The interlayer insulating layer ILD may be a composite layer including at least one of silicon oxide, silicon nitride, silicon oxynitride, or porous low-k dielectric materials. Interconnection lines 60 may be provided in the interlayer insulating layer ILD. The floating diffusion region FD may be connected to the interconnection lines 60. The interconnection lines 60 and the interlayer insulating layer ILD may constitute a pixel circuit layer. The pixel circuit layer may be provided on the first surface 100A of the substrate 100.

According to an embodiment, a first anti-reflection layer 42 may be provided on the deep device isolation pattern DTI. The first anti-reflection layer 42 may be provided on the second surface 100B of the substrate 100 to cover the second surface 100B.

The first anti-reflection layer 42 may include an oxide material. In an embodiment, the first anti-reflection layer 42 may be formed of or include at least one of Al₂O₃, HfO, SiO₂, or PTEOS.

According to an embodiment, light-blocking patterns 48 may be provided on the first anti-reflection layer 42. The light-blocking patterns 48 may be provided between the color filters. Low-refractive patterns 50 may be provided on the light-blocking patterns 48, respectively. In an embodiment, the light-blocking pattern 48 and the low-refractive pattern 50 may be overlap the deep device isolation pattern DTI and may have a grid shape in a plan view. The light-blocking pattern 48 and the low-refractive pattern 50 may not be overlapped with the deep device isolation pattern DTI and may have a grid shape in a plan view. The light-blocking pattern 48 may be formed of or include, for example, titanium. The low-refractive patterns 50 may have substantially the same thickness and may be formed of or include the same organic material. The low-refractive pattern 50 may have a refractive index lower than the color filters. The light-blocking pattern 48 and the low-refractive pattern 50 may prevent a cross-talk issue from occurring between adjacent ones of the pixel regions PR.

According to an embodiment, a second anti-reflection layer 43 may be provided on color filters CF. The second anti-reflection layer 43 may cover the color filters CF. The second anti-reflection layer 43 may be formed of an insulating material whose refractive index is different from that of the substrate 100.

Referring to FIGS. 3B, 4, 5, and 6, the image sensor 300 in the center pixel region X, the middle pixel region Y, and the edge pixel region Z will be described in more detail.

The center color filter group on the center pixel region X, the middle color filter group on the middle pixel region Y, and the edge color filter group on the edge pixel region Z may include a plurality of blue color filters, a plurality of green color filters, and a plurality of red color filters, respectively.

Referring to FIGS. 3B, 3C, and 4, the image sensor 300 in the center pixel region X will be described in more detail. The center pixel region X may be defined as a pixel region in a center portion of a substrate in a plan view. The center pixel region X may include the center color filter group on the center pixel region X. The center pixel region X may include the color filters CF of the center color filter group and a plurality of photoelectric conversion parts PD corresponding thereto.

In an embodiment, the center color filter group may include a center first wavelength band filter CFBx, a center second wavelength band filter CFGx, and a center third wavelength band filter CFRx, which are configured to pass light within different wavelength bands.

Referring to FIG. 4, the center first wavelength band filter CFBx may include a center (1-1)-th wavelength band filter CF1Bx, a center (1-2)-th wavelength band filter CF2Bx, a center (1-3)-th wavelength band filter CF3Bx, and a center (1-4)-th wavelength band filter CF4Bx. In an embodiment, the center first wavelength band filters CF1Bx, CF2Bx, CF3Bx, and CF4Bx may be sequentially provided in a counter-clockwise direction. The center first wavelength band filters CF1Bx, CF2Bx, CF3Bx, and CF4Bx may be configured to pass light within the same wavelength band. The center first wavelength band filters CF1Bx, CF2Bx, CF3Bx, and CF4Bx may be configured to pass light having a wavelength ranging from 350 nm to 550 nm. The center first wavelength band filters CF1Bx, CF2Bx, CF3Bx, and CF4Bx may be configured to pass a fraction of light which has a wavelength outside the wavelength band of 350 nm to 550 nm.

The center (1-1)-th wavelength band filter CF1Bx may correspond to a center (1-1)-th wavelength photoelectric conversion part PD1Bx. The center (1-1)-th wavelength band filter CF1Bx may be provided on the center (1-1)-th wavelength photoelectric conversion part PD1Bx. The center (1-1)-th wavelength photoelectric conversion part PD1Bx and the center (1-1)-th wavelength band filter CF1Bx may not be shifted from each other. The center first wavelength band filter CFBx may not be shifted from a corresponding one of the center first wavelength photoelectric conversion parts PD. The center (1-1)-th wavelength band filter CF1Bx may be provided to fully overlap with the center (1-1)-th wavelength photoelectric conversion part PD1Bx. The center first wavelength band filter CFBx may be provided to fully overlap with a corresponding one of the center first wavelength photoelectric conversion parts PD. For example, the center (1-1)-th wavelength photoelectric conversion part PD1Bx may be defined between adjacent ones of the deep device isolation patterns DTI in the center pixel region X, and the center (1-1)-th wavelength band filter CF1Bx may be provided between adjacent ones of the light-blocking patterns 48, which are overlapped with the deep device isolation patterns DTI. In an embodiment, the center (1-2)-th to (1-4)-th wavelength band filters CF2Bx, CF3Bx, and CF4Bx may be provided to have substantially the same features as the center (1-1)-th wavelength band filter CF1Bx.

According to an embodiment, center first wavelength band filter microlens MLBx may be provided on the center first wavelength band filter CFBx. For example, the center first wavelength band filter microlens MLBx may overlap the center (1-1)-th to (1-4)-th wavelength band filters CF1Bx, CF2Bx, CF3Bx, and CF4Bx. The center first wavelength band filter microlens MLBx may correspond to four first wavelength photoelectric conversion parts PD1Bx, PD2Bx, PD3Bx, and PD4Bx. For example, the center (1-1)-th wavelength photoelectric conversion part PD1Bx may correspond to the center (1-1)-th wavelength band filters CF1Bx, the center (1-2)-th wavelength photoelectric conversion part PD2Bx may correspond to the center (1-2)-th wavelength band filters CF2Bx, the center (1-3)-th wavelength photoelectric conversion part PD3Bx may correspond to the center (1-3)-th wavelength band filters CF3Bx, and the center (1-4)-th wavelength photoelectric conversion part PD4Bx may correspond to the center (1-4)-th wavelength band filters CF4Bx.

An end portion of the center first wavelength band filter microlens MLBx may overlap a deep device isolation pattern DTI. An opposite end portion of the center first wavelength band filter microlens MLBx may overlap another deep device isolation pattern DTI. A center portion of each of the center (1-1)-th to (1-4)-th wavelength photoelectric conversion parts PD1Bx, PD2Bx, PD3Bx, and PD4Bx, which are provided in a counter-clockwise direction, and a center portion of the center first wavelength band filter microlens MLBx corresponding thereto may be located on the same line in the second direction D2. In other words, the center portion of each of the center (1-1)-th to (1-4)-th wavelength photoelectric conversion parts PD1Bx, PD2Bx, PD3Bx, and PD4Bx, which are provided in the counter-clockwise direction, may be overlapped with the center portion of the center first wavelength band filter microlens MLBx corresponding thereto.

The center second wavelength band filter CFGx may be provided to be adjacent to the center first wavelength band filter CFBx in the third direction D3. The center second wavelength band filter CFGx may include a center (2-1)-th wavelength band filter CF1Gx, a center (2-2)-th wavelength band filter CF2Gx, a center (2-3)-th wavelength band filter CF3Gx, and a center (2-4)-th wavelength band filter CF4Gx. In an embodiment, the center (2-1)-th to (2-4)-th wavelength band filters CF1Gx, CF2Gx, CF3Gx, and CF4Gx may be sequentially provided in a counter-clockwise direction.

The center second wavelength band filters CF1Gx, CF2Gx, CF3Gx, and CF4Gx may be configured to pass light having a wavelength within the same wavelength band. For example, the center second wavelength band filters CF1Gx, CF2Gx, CF3Gx, and CF4Gx may be configured to pass light having a wavelength ranging from 450 nm to 650 nm. The center second wavelength band filters CF1Gx, CF2Gx, CF3Gx, and CF4Gx may be configured to pass a fraction of light which has a wavelength outside the wavelength band of 450 nm to 650 nm. Light passing through the center second wavelength band filters CF1Gx, CF2Gx, CF3Gx, and CF4Gx may have a wavelength that is greater than light passing through the center first wavelength band filters CF1Bx, CF2Bx, CF3Bx, and CF4Bx.

The center (2-1)-th wavelength band filter CF1Gx may correspond to a center (2-1)-th wavelength photoelectric conversion part PD1Gx. The center (2-1)-th wavelength band filter CF1Gx may be provided on the center (2-1)-th wavelength photoelectric conversion part PD1Gx. The center (2-1)-th wavelength photoelectric conversion part PD1Bx and the center (2-1)-th wavelength band filter CF1Gx may not be shifted from each other. The center second wavelength band filter CFGx may not be shifted from a corresponding one of the center second wavelength photoelectric conversion parts PD. The center (2-1)-th wavelength band filter CF1Gx may be provided to fully overlap with the center (2-1)-th wavelength photoelectric conversion part PD1Gx. The center second wavelength band filter CFGx may be provided to fully overlap with a corresponding one of the center second wavelength photoelectric conversion parts PD. For example, the center (2-1)-th wavelength photoelectric conversion part PD1Gx may be defined between adjacent ones of the deep device isolation patterns DTI in the center pixel region X, and the center (2-1)-th wavelength band filter CF1Gx may be provided between adjacent ones of the light-blocking patterns 48, which are overlapped with the deep device isolation patterns DTI. In an embodiment, the center (2-2)-th to (2-4)-th wavelength band filters CF2Gx, CF3Gx, and CF4Gx may be provided to have substantially the same features as the center (2-1)-th wavelength band filter CF1Gx.

A center second wavelength band filter microlens MLGx may be provided on the center second wavelength band filter CFGx. In an embodiment, the center second wavelength band filter microlens MLGx may overlap the center (2-1)-th to (2-4)-th wavelength band filters CF1Gx, CF2Gx, CF3Gx, and CF4Gx. microlens

An end portion of the center second wavelength band filter microlens MLGx may overlap one deep device isolation pattern DTI. Another end portion of the center second wavelength band filter microlens MLGx may overlap another deep device isolation pattern DTI. A center portion of each of the center (2-1)-th to (2-4)-th wavelength photoelectric conversion parts PD1Gx, PD2Gx, PD3Gx, and PD4Gx, which are provided in a counter-clockwise direction, and a center portion of the center second wavelength band filter microlens MLGx corresponding thereto may be located on the same line in the second direction D2. In other words, the center portion of each of the center (2-1)-th to (2-4)-th wavelength photoelectric conversion parts PD1Gx, PD2Gx, PD3Gx, and PD4Gx, which are provided in the counter-clockwise direction, may be overlapped with the center portion of the center second wavelength band filter microlens MLGx corresponding thereto. For example, the center (2-1)-th wavelength photoelectric conversion part PD1Gx may correspond to the center (2-1)-th wavelength band filters CF1Gx, the center (2-2)-th wavelength photoelectric conversion part PD2Gx may correspond to the center (2-2)-th wavelength band filters CF2Gx, the center (2-3)-th wavelength photoelectric conversion part PD3Gx may correspond to the center (2-3)-th wavelength band filters CF3Gx, and the center (2-4)-th wavelength photoelectric conversion part PD4Gx may correspond to the center (2-4)-th wavelength band filters CF4Gx.

The center first wavelength band filter microlens MLBx on the center first wavelength band filter CFBx may have a diameter that is different from that of the center second wavelength band filter microlens MLGx on the center second wavelength band filter CFGx.

The height MLBxH of the center first wavelength band filter microlens MLBx may be equal to a height MLGxH of the center second wavelength band filter microlens MLGx. A width MLBxW of the center first wavelength band filter microlens MLBx may be larger than a width MLGxW of the center second wavelength band filter microlens MLGx. In other words, a diameter of the center first wavelength band filter microlens MLBx may be larger than a diameter of the center second wavelength band filter microlens MLGx. A curvature of the center first wavelength band filter microlens MLBx may be different from a curvature of the center second wavelength band filter microlens MLGx. The microlenses may have different diameters from each other, depending on the kind of the color filter. At least two of the microlenses covering the center color filter group may be provided to have different diameters from each other. At least two of the microlenses covering the center color filter group may be provided to have different curvatures from each other.

In the center pixel region X, a width CF1BxW of the center (1-1)-th wavelength band filter CF1Bx may be equal to a width CF2BxW of the center (1-2)-th wavelength band filter CF2Bx. A width CF1GxW of the center (2-1)-th green filter CF1Gx may be equal to a width CF2GxW of the center (2-2)-th green filter CF2Gx. The width CF1BxW of the center (1-1)-th wavelength band filter CF1Bx may be different from the width CF1GxW of the center (2-1)-th wavelength band filter CF1Gx.

In the center pixel region X, two adjacent ones of the photoelectric conversion parts PD may be overlapped with two adjacent ones of the color filters CF and one of the microlenses. For example, the center (1-1)-th and (1-2)-th wavelength photoelectric conversion parts PD1Bx and PD2Bx, which are adjacent to each other, may be overlapped with the center (1-1)-th and (1-2)-th wavelength band filters CF1Bx and CF2Bx and the center first wavelength band filter microlens MLBx. However, the disclosure is not limited thereto, and as such, according to another embodiment, one of the microlenses may overlap three or more photoelectric conversion parts PD and three color filters CF consecutively arranged next to each other.

In the center pixel region X, the deep device isolation pattern DTI between adjacent ones of the photoelectric conversion parts PD may be overlapped with a boundary between the color filters CF corresponding to the adjacent ones of the photoelectric conversion parts PD. For example, the deep device isolation pattern DTI between the center (1-1)-th and (1-2)-th wavelength photoelectric conversion parts PD1Bx and PD2Bx, which are adjacent to each other, may be overlapped with a boundary between the center (1-1)-th and (1-2)-th wavelength band filters CF1Bx and CF2Bx, which are adjacent to each other.

The center (2-1)-th wavelength photoelectric conversion part PD1Gx, the center (2-2)-th wavelength photoelectric conversion part PD2Gx, the center (2-1)-th wavelength band filter CF1Gx, and the center (2-2)-th wavelength band filter CF2Gx in the center pixel region X may be provided to have substantially the same features as described above.

Referring to FIG. 3C, the center pixel region X may include a center third wavelength band filter CFRx. The center third wavelength band filter CFRx may include a plurality of center third wavelength band filters CFRx. In an embodiment, the center third wavelength band filters CFRx may be configured to pass light having a wavelength ranging from 550 nm to 700 nm. The center third wavelength band filters CFRx may be configured to pass a fraction of light which has a wavelength outside the wavelength band of 550 nm to 700 nm. Light passing through the center third wavelength band filters CFRx may have a wavelength that is greater than light passing through the center first wavelength band filters CFBx. Light passing through the center third wavelength band filters CFRx may have a wavelength that is greater than light passing through the center second wavelength band filters CFGx.

In the center pixel region X, a diameter of the microlens MLBx on the center first wavelength band filters CFBx may be larger than a diameter of the microlens MLGx on the center second wavelength band filters CFGx. The diameter of the microlens MLGx on the center second wavelength band filters CFGx may be larger than a diameter of the microlens MLRx on the center third wavelength band filters CFRx.

In the center pixel region X, the microlens MLBx on the center first wavelength band filters CFBx, the microlens MLGx on the center second wavelength band filters CFGx, the microlens MLRx on the center third wavelength band filters CFRx may have curvatures that are different from each other.

Referring to FIGS. 3B, 3D, and 5, the image sensor 300 in the middle pixel region Y will be described in more detail below. The middle pixel region Y may be defined as a region surrounding the center pixel region X of the substrate in a plan view. The middle pixel region Y may include the middle color filter group on the middle pixel region Y. The middle pixel region Y may include the color filters CF of the middle color filter group and a plurality of photoelectric conversion parts PD corresponding thereto.

In an embodiment, the middle color filter group may include middle first wavelength band filters CFBy, middle second wavelength band filters CFGy, and middle third wavelength band filters CFRy, which are configured to pass light within different wavelength bands.

The middle second wavelength band filter CFGy may include a middle (2-1)-th wavelength band filter CF1Gy, a middle (2-2)-th wavelength band filter CF2Gy, a middle (2-3)-th wavelength band filter CF3Gy, and a middle (2-4)-th wavelength band filter CF4Gy. The middle (2-1)-th to (2-4)-th middle green filters CF1Gy, CF2Gy, CF3Gy, and CF4Gy may be sequentially provided in a counter-clockwise direction.

The middle (2-1)-th wavelength band filter CF1Gy may correspond to a middle (2-1)-th wavelength photoelectric conversion part PD1Gy. The middle (2-1)-th wavelength band filters CF1Gy may be provided on the middle (2-1)-th wavelength photoelectric conversion part PD1Gy. The middle (2-1)-th wavelength photoelectric conversion part PD1Gy may be shifted from the middle (2-1)-th wavelength band filters CF1Gy.

The middle (2-1)-th wavelength band filters CF1Gy may be provided to overlap with a portion of the middle (2-1)-th wavelength photoelectric conversion part PD1Gy. For example, the middle (2-1)-th wavelength photoelectric conversion part PD1Gy may be provided between adjacent ones of the deep device isolation pattern DTI in the middle pixel region Y, and the deep device isolation pattern DTI may not be overlapped with a corresponding one of the light-blocking patterns 48.

Since the light-blocking pattern 48 corresponding to the deep device isolation pattern DTI in the middle pixel region Y is not overlapped with the deep device isolation pattern DTI, the middle (2-1)-th wavelength photoelectric conversion part PD1Gy and the middle (2-1)-th wavelength band filters CF1Gy may be partially overlapped with each other. The middle (2-1)-th wavelength photoelectric conversion part PD1Gy may be shifted from the middle (2-1)-th wavelength band filters CF1Gy. In an embodiment, the middle (2-2)-th to (2-4)-th wavelength band filters CF2Gy, CF3Gy, and CF4Gy may be provided to have substantially the same features as the middle (2-1)-th wavelength band filters CF1Gy.

Middle second wavelength band filter microlens MLGy may be provided on the middle second wavelength band filters CFGy. In an embodiment, the middle second wavelength band filter microlens MLGy may be partially overlapped with the middle (2-1)-th to (2-4)-th wavelength band filters CF1Gy, CF2Gy, CF3Gy, and CF4Gy. An end portion of the middle second wavelength band filter microlens MLGy may not be overlapped with a deep device isolation pattern DTI. The middle second wavelength band filter microlens MLGy may be shifted from the middle second wavelength band filters CFGy.

A center portion of the middle (2-1)-th to (2-4)-th wavelength photoelectric conversion parts PD1Gy, PD2Gy, PD3Gy, and PD4Gy, which are provided in a counter-clockwise direction, and a center portion of the middle second wavelength band filter microlens MLGy corresponding thereto may not be located on the same line in the second direction D2. For example, the middle (2-1)-th wavelength photoelectric conversion part PD1Gy may correspond to the middle (2-1)-th wavelength band filters CF1Gy, the middle (2-2)-th wavelength photoelectric conversion part PD2Gy may correspond to the middle (2-2)-th wavelength band filters CF2Gy, the middle (2-3)-th wavelength photoelectric conversion part PD3Gy may correspond to the middle (2-3)-th wavelength band filters CF3Gy, and the middle (2-4)-th wavelength photoelectric conversion part PD4Gy may correspond to the middle (2-4)-th wavelength band filters CF4Gy.

In other words, the center portion of each of the middle (2-1)-th to (2-4)-th wavelength photoelectric conversion parts PD1Gy, PD2Gy, PD3Gy, and PD4Gy, which are provided in the counter-clockwise direction, may not be overlapped with the center portion of the middle second wavelength band filter microlens MLGy corresponding thereto.

Each of the middle second wavelength photoelectric conversion parts PD1Gy, PD2Gy, PD3Gy, and PD4Gy may be shifted from the middle second wavelength band filter microlens MLGy corresponding thereto.

The middle third wavelength band filters CFRy may be provided to be adjacent to the middle second wavelength band filters CFGy in the third direction D3.

The middle third wavelength band filters CFRy may include a middle (3-1)-th wavelength band filter CF1Ry, a middle (3-2)-th wavelength band filter CF2Ry, a middle (3-3)-th wavelength band filter CF3Ry, and a middle (3-4)-th wavelength band filter CF4Ry. The middle (3-1)-th to (3-4)-th wavelength band filters CF1Ry, CF2Ry, CF3Ry, and CF4Ry may be sequentially provided in a counter-clockwise direction.

The middle (3-1)-th wavelength band filter CF1Ry may correspond to a middle (3-1)-th wavelength photoelectric conversion part PD1Ry. The middle (3-1)-th wavelength band filter CF1Ry may be provided on the middle (3-1)-th wavelength photoelectric conversion part PD1Ry. The middle (3-1)-th wavelength photoelectric conversion part PD1Ry may be shifted from the middle (3-1)-th wavelength band filter CF1Ry.

The middle (3-1)-th wavelength band filter CF1Ry may be provided to overlap with a portion of the middle (3-1)-th wavelength photoelectric conversion part PD1Ry. For example, the middle (3-1)-th wavelength photoelectric conversion part PD1Ry may be provided between adjacent ones of the deep device isolation patterns DTI in the middle pixel region Y, and the middle (3-1)-th wavelength band filter CF1Ry may be provided between adjacent ones of the light-blocking patterns 48 corresponding to the deep device isolation patterns DTI. In an embodiment, the middle (3-2)-th to (3-4)-th wavelength band filters CF2Ry, CF3Ry, and CF4Ry may be provided to have substantially the same features as the middle (3-1)-th wavelength band filters CF1Ry.

A middle third wavelength band filter microlens MLRy may be provided on the middle third wavelength band filters CFRy. In an embodiment, the middle third wavelength band filter microlens MLRy may overlap the middle (3-1)-th to (3-4)-th wavelength band filters CF1Ry, CF2Ry, CF3Ry, and CF4Ry. An end portion of the middle third wavelength band filter microlens MLRy may be overlapped with the middle (2-2)-th wavelength photoelectric conversion part PD2Gy. Another end portion of the middle third wavelength band filter microlens MLRy may overlap the middle (3-2)-th wavelength photoelectric conversion part PD2Ry.

A center portion of each of the middle (3-1)-th to (3-4)-th wavelength photoelectric conversion parts PD1Ry, PD2Ry, PD3Ry, and PD4Ry, which are provided in a counter-clockwise direction, and a center portion of the middle third wavelength band filter microlens MLRy corresponding thereto may not be located on the same line in the second direction D2. For example, the middle (3-1)-th wavelength photoelectric conversion part PD1Ry may correspond to the middle (3-1)-th wavelength band filters CF1Ry, the middle (3-2)-th wavelength photoelectric conversion part PD2Ry may correspond to the middle (3-2)-th wavelength band filters CF2Ry, the middle (3-3)-th wavelength photoelectric conversion part PD3Ry may correspond to the middle (3-3)-th wavelength band filters CF3Ry, and the middle (3-4)-th wavelength photoelectric conversion part PD4Ry may correspond to the middle (3-4)-th wavelength band filters CF4Ry.

That is, the deep device isolation pattern DTI between adjacent ones of the photoelectric conversion parts PD in the middle pixel region Y may not be overlapped with a boundary between the color filters CF corresponding to the adjacent ones of the photoelectric conversion parts PD.

A height MLGyH of the middle second wavelength band filter microlens MLGy may be equal to a height MLRyH of the middle third wavelength band filter microlens MLRy. A width MLRyW of the middle third wavelength band filter microlens MLRy may be smaller than a width MLGyW of the middle second wavelength band filter microlens MLGy. In other words, a diameter of the middle third wavelength band filter microlens MLRy may be smaller than a diameter of a middle green filter microlens MLGy. A curvature of the middle third wavelength band filter microlens MLRy may be different from a curvature of the middle second wavelength band filter microlens MLGy. The microlenses may have different diameters from each other, depending on the kind of the color filter. At least two of the microlenses covering the middle color filter group may be provided to have different diameters from each other. At least two of the microlenses covering the middle color filter group may be provided to have different curvatures from each other.

In the middle pixel region Y, a width CF1GyW of the middle (2-1)-th wavelength band filter CF1Gy may be equal to a width CF2GyW of the middle (2-2)-th wavelength band filter CF2Gy. A width CF1RyW of the middle (3-1)-th wavelength band filter CF1Ry may be equal to a width CF2RyW of the middle (3-2)-th wavelength band filter CF2Ry. The width CF1GyW of the middle (2-1)-th wavelength band filter CF1Gy may be different from the width CF1RyW of the middle (3-1)-th wavelength band filter CF1Ry.

In the middle pixel region Y, two adjacent ones of the photoelectric conversion parts PD may be shifted from two adjacent ones of the color filters CF. Two adjacent ones of the photoelectric conversion parts PD may be shifted from a corresponding microlens.

The middle (3-1)-th wavelength photoelectric conversion part PD1Ry may be interposed between the deep device isolation pattern DTI, which are adjacent to and spaced apart from each other. The deep device isolation pattern DTI may be interposed between the middle (3-1)-th and (3-2)-th wavelength photoelectric conversion parts PD1Ry and PD2Ry.

The deep device isolation pattern DTI, which is closest to the middle (3-1)-th wavelength photoelectric conversion part PD1Ry and is spaced apart from the middle (3-2)-th wavelength photoelectric conversion part PD2Ry, may have a center point CPy. The center point CPy may be defined as an intersection point between a center portion of the deep device isolation pattern DTI and the second surface 100B of the substrate 100.

In a plan view, a distance from the center point CPy to a side surface of the first middle red color filter CF1Ry, which is closest to the center point CPy, may be defined as a middle color filter shift distance dsy1. In other words, a distance from an extension line, which passes through the center point CPy in the second direction D2 to a side surface of the first middle red color filter CF1Ry, which is closest to the center point CPy, may be defined as the middle color filter shift distance dsy1. That is, in the middle pixel region Y, a distance between the deep device isolation pattern DTI and a side surface of the color filter CF1Ry corresponding to the deep device isolation pattern DTI may be defined as the middle color filter shift distance dsy1.

In a plan view, a distance from the center point CPy to an end portion of the middle red microlens MLRy closest to the center point CPy may be defined as a middle lens shift distance dsy2. In other words, a distance from an extension line, which passes through the center point CPy in the second direction D2 to an end portion of the microlens MLRy, which is closest to the center point CPy, may be defined as the middle lens shift distance dsy2. That is, in the middle pixel region Y, a distance between the deep device isolation pattern DTI and the outermost portion of the microlens MLRy corresponding to the deep device isolation pattern DTI may be defined as the middle lens shift distance dsy2. That is, the middle color filter shift distance dsy1 may be smaller than the middle lens shift distance dsy2.

Other color filters in the middle pixel region Y may be provided to have substantially the same features as described above.

According to an embodiment, between the color filters of the same color, the microlenses covering the color filter group of the center pixel region X may have diameters that are different from the microlenses covering the color filter group of the middle pixel region Y.

For example, a diameter of the center second wavelength band filter microlens MLGx of the center pixel region X may be larger than a diameter of the middle second wavelength band filter microlens MLGy of the middle pixel region Y.

Referring to FIGS. 3B, 3C, and 6, the image sensor 300 in the edge pixel region Z will be described in more detail. The edge pixel region Z may be defined as a region surrounding the middle pixel region Y of the substrate in a plan view. The edge pixel region Z may include the edge color filter group on the edge pixel region Z. The edge pixel region Z may include the color filters CF of the edge color filter group and a plurality of photoelectric conversion parts PD corresponding thereto.

In an embodiment, the edge color filter group may include edge first wavelength band filters CFBz, edge second wavelength band filters CFGz, and edge third wavelength band filters CFRz.

The edge second wavelength band filters CFGz may include an edge (2-1)-th wavelength band filter CF1Gz, an edge (2-2)-th wavelength band filter CF2Gz, an edge (2-3)-th wavelength band filter CF3Gz, and an edge (2-4)-th wavelength band filter CF4Gz. In an embodiment, the edge (2-1)-th to (2-4)-th wavelength band filters CF1Gz, CF2Gz, CF3Gz, and CF4Gz may be sequentially provided in a counter-clockwise direction.

The edge (2-1)-th wavelength band filter CF1Gz may correspond to a first edge green photoelectric conversion part PD1Grz. The edge (2-1)-th wavelength band filter CF1Gz may be provided on the edge (2-1)-th wavelength photoelectric conversion part PD1Gz. The edge (2-1)-th wavelength photoelectric conversion part PD1Gz may be shifted from the edge (2-1)-th wavelength band filter CF1Gz.

The edge (2-1)-th wavelength band filter CF1Gz may be provided to partially overlap with the edge (2-1)-th wavelength photoelectric conversion part PD1Gy. For example, the edge (2-1)-th wavelength photoelectric conversion part PD1Gz may be defined between adjacent ones of the deep device isolation patterns DTI in the edge pixel region Z, and the deep device isolation pattern DTI may not be overlapped with a corresponding one of the light-blocking patterns 48.

Since the light-blocking pattern 48 corresponding to the deep device isolation pattern DTI in the edge pixel region Z is not overlapped with the deep device isolation pattern DTI, the edge (2-1)-th wavelength photoelectric conversion part PD1Gz and the edge (2-1)-th wavelength band filter CF1Gz may be partially overlapped with each other. The edge (2-1)-th wavelength photoelectric conversion part PD1Gz may be shifted from the edge (2-1)-th wavelength band filter CF1Gz. In an embodiment, the edge (2-2)-th to (2-4)-th wavelength band filters CF2Gz, CF3Gz, and CF4Gz may be provided to have substantially the same features.

Edge second wavelength band filter microlens MLGz may be provided on the edge second wavelength band filters CFGz. In an embodiment, the edge second wavelength band filter microlens MLGz may be partially overlapped with the edge (2-1)-th to (2-4)-th wavelength band filters CF1Gz, CF2Gz, CF3Gz, and CF4Gz. An end portion of the edge second wavelength band filter microlens MLGz may not be overlapped with a deep device isolation pattern DTI. The edge second wavelength band filter microlens MLGz may be shifted from the edge second wavelength band filters CFGz. The shifting distances of the edge second wavelength band filter microlens MLGz and the edge second wavelength band filters CFGz may be larger than those of the middle second wavelength band filter microlens MLGy and the middle second wavelength band filters CFGy.

A center portion of each of the edge (2-1)-th to (2-4)-th wavelength

photoelectric conversion parts PD1Gz, PD2Gz, PD3Gz, and PD4Gz, which are provided in a counter-clockwise direction, and a center portion of the edge second wavelength band filter microlens MLGz corresponding thereto may not be located on the same line in the second direction D2. For example, the edge (2-1)-th wavelength photoelectric conversion part PD1Gz may correspond to the edge (2-1)-th wavelength band filters CF1Gz, the edge (2-2)-th wavelength photoelectric conversion part PD2Gz may correspond to the edge (2-2)-th wavelength band filters CF2Gz, the edge (2-3)-th wavelength photoelectric conversion part PD3Gz may correspond to the edge (2-3)-th wavelength band filters CF3Gz, and the edge (2-4)-th wavelength photoelectric conversion part PD4Gz may correspond to the edge (2-4)-th wavelength band filters CF4Gz.

In other words, the center portion of each of the edge (2-1)-th to (2-4)-th wavelength photoelectric conversion parts PD1Gz, PD2Gz, PD3Gz, and PD4Gz, which are provided in a counter-clockwise direction, may not be overlapped with the center portion of the edge second wavelength band filter microlens MLGz corresponding thereto.

The edge second wavelength photoelectric conversion parts PD1Gz, PD2Gz, PD3Gz, and PD4Gz may be shifted from corresponding ones of the edge second wavelength band filter microlens MLGz.

The edge third wavelength band filters CFRz may be provided to be adjacent to the edge second wavelength band filters CFGz in the third direction D3.

The edge third wavelength band filters CFRz may include an edge (3-1)-th wavelength band filter CF1Rz, an edge (3-2)-th wavelength band filter CF2Rz, a third edge red filter CF3Rz, and a fourth edge red filter CF4Rz. In an embodiment, the edge (3-1)-th, (3-2)-th, third, and fourth edge red filters CF1Rz, CF2Rz, CF3Rz, and CF4Rz may be sequentially provided in a counter-clockwise direction.

The edge (3-1)-th wavelength band filter CF1Rz may correspond to an edge (3-1)-th wavelength photoelectric conversion part PD1Rz. The edge (3-1)-th wavelength band filter CF1Rz may be provided on the edge (3-1)-th wavelength photoelectric conversion part PD1Rz. The edge (3-1)-th wavelength photoelectric conversion part PD1Rz may be shifted from the edge (3-1)-th wavelength band filter CF1Rz.

The edge (3-1)-th wavelength band filter CF1Rz may be provided to overlap with a portion of the edge (3-1)-th wavelength photoelectric conversion part PD1Rz. For example, the edge (3-1)-th wavelength photoelectric conversion part PD1Rz may be provided between adjacent ones of the deep device isolation patterns DTI in the edge pixel region Z, and the edge (3-1)-th wavelength band filter CF1Rz may be provided between adjacent ones of the light-blocking patterns 48 corresponding to the deep device isolation patterns DTI. In an embodiment, the edge (3-2)-th to (3-4)-th wavelength band filters CF2Rz, CF3Rz, and CF4Rz may be provided to have substantially the same features.

An edge third wavelength band filter microlens MLRz may be provided on the edge third wavelength band filters CFRz. For example, the edge third wavelength band filter microlens MLRz may overlap the edge (3-1)-th to (3-4)-th wavelength band filters CF1Rz, CF2Rz, CF3Rz, and CF4Rz. An end portion of the edge third wavelength band filter microlens MLRz may overlap the edge (2-2)-th wavelength photoelectric conversion part PD2Gz. Another end portion of the edge third wavelength band filter microlens MLRz may overlap the edge (3-2)-th wavelength photoelectric conversion part PD2Rz.

A center portion of each of the edge (3-1)-th to (3-4)-th wavelength photoelectric conversion parts PD1Rz, PD2Rz, PD3Rz, and PD4Rz, which are provided in a counter-clockwise direction, and a center portion of the edge third wavelength band filter microlens MLRz corresponding thereto may not be located on the same line in the second direction D2. For example, the edge (3-1)-th wavelength photoelectric conversion part PD1Rz may correspond to the edge (3-1)-th wavelength band filters CF1Rz, the edge (3-2)-th wavelength photoelectric conversion part PD2Rz may correspond to the edge (3-2)-th wavelength band filters CF2Rz, the edge (3-3)-th wavelength photoelectric conversion part PD3Rz may correspond to the edge (2-3)-th wavelength band filters CF3Rz, and the edge (3-4)-th wavelength photoelectric conversion part PD4Rz may correspond to the edge (3-4)-th wavelength band filters CF4Rz.

That is, the deep device isolation pattern DTI between adjacent ones of the photoelectric conversion parts PD in the edge pixel region Z may not be overlapped with a boundary between the color filters CF corresponding to the adjacent ones of the photoelectric conversion parts PD.

A height MLGzH of the edge second wavelength band filter microlens MLGz may be equal to a height MLRzH of the edge third wavelength band filter microlens MLRz. A width MLRzW of the edge third wavelength band filter microlens MLRz may be smaller than a width MLGzW of the edge second wavelength band filter microlens MLGz. In other words, a diameter of the edge third wavelength band filter microlens MLRz may be smaller than a diameter of the edge second wavelength band filter microlens MLGz. A curvature of the edge third wavelength band filter microlens MLRz may be equal to a curvature of the edge second wavelength band filter microlens MLGz.

In the edge pixel region Z, the microlenses may have different diameters from each other, depending on the kind of the color filter. At least two of the microlenses covering the edge color filter group may be provided to have different diameters from each other. At least two of the microlenses covering the edge color filter group may be provided to have different curvatures from each other.

In the edge pixel region Z, a width CF1GzW of the edge (2-1)-th wavelength band filter CF1Gz may be equal to a width CF2GzW of the edge (2-2)-th edge green filter CF2Gz. A width CF1RzW of the edge (3-1)-th wavelength band filter CF1Rz may be equal to a width CF2RzW of the edge (3-2)-th wavelength band filter CF2Rz. The width CF1GzW of the edge (2-1)-th wavelength band filter CF1Gz may be different from the width CF1RzW of the edge (3-1)-th wavelength band filter CF1Rz.

In the edge pixel region Z, two adjacent ones of the photoelectric conversion parts PD may be shifted from two adjacent ones of the color filters CF. Two adjacent ones of the photoelectric conversion parts PD may be shifted from a corresponding microlens.

The edge (3-1)-th wavelength photoelectric conversion part PD1Rz may be interposed between the deep device isolation patterns DTI, which are spaced apart from each other and adjacent to each other. The deep device isolation pattern DTI may be interposed between the edge (3-1)-th wavelength photoelectric conversion part PD1Rz and the edge (3-2)-th wavelength photoelectric conversion part PD2Rz.

The deep device isolation pattern DTI, which is closest to the edge (3-1)-th wavelength photoelectric conversion part PD1Rz and is spaced apart from the edge (3-2)-th wavelength photoelectric conversion part PD2Rz, may have a center point CPz. The center point CPz may be defined as an intersection point between a center portion of the deep device isolation pattern DTI and the second surface 100B of the substrate 100.

In a plan view, a distance from the center point CPz to a side surface of a first edge red color filter CF1Rz closest to the center point CPz may be defined as an edge color filter shift distance dsz1. In an embodiment, a distance from an extension line, which passes through the center point CPz in the second direction D2, to a side surface of the first edge red color filter CF1Rz, which is closest to the center point CPz, may be defined as the edge color filter shift distance dsz1. That is, in the edge pixel region Z, a distance from the deep device isolation pattern DTI to a side surface of the color filter CF1Rz corresponding to the deep device isolation pattern DTI may be defined as the edge color filter shift distance dsz1.

In a plan view, a distance from the center point CPz to an end portion of the edge red microlens MLRz closest to the center point CPz may be defined as an edge lens shift distance dsz2. That is, a distance from an extension line, which passes through the center point CPz in the second direction D2, to an end portion of the microlens MLRz, which is closest to the center point CPz, may be defined as a middle lens shift distance dsz2. That is, in the edge pixel region Z, a distance from the deep device isolation pattern DTI to the outermost portion of the microlens MLRz corresponding to the deep device isolation pattern DTI may be defined as the edge lens shift distance dsz2.

The edge color filter shift distance dsz1 may be smaller than the edge lens shift distance dsz2. The edge color filter shift distance dsz1 in the edge pixel region Z may be larger than the middle color filter shift distance dsy1 in the middle pixel region Y. The edge lens shift distance dsz2 in the edge pixel region Z may be larger than the middle lens shift distance dsy2 in the middle pixel region Y.

Other color filters in the edge pixel region Z may be provided to have substantially the same features as described above.

Between the color filters of the same color, the microlenses covering the color filter group of the middle pixel region Y may have diameters that are larger than the microlenses covering the color filter group of the edge pixel region Z.

For example, a diameter of the middle green filter microlens MLGy of the middle pixel region Y may be larger than a diameter of the edge second wavelength band filter microlens MLGz of the edge pixel region Z.

The microlenses may have different diameter from each other, depending on the kinds of corresponding color filters in the same pixel region.

For example, in the edge pixel region Z, the microlens MLRz corresponding to the third wavelength band filters CFRz may have a diameter that is smaller than that of the microlens MLGz corresponding to the second wavelength band filters CFGz. In the edge pixel region Z, the microlens MLGz corresponding to the second wavelength band filters CFGz may have a diameter that is smaller than that of the microlens corresponding to the edge first wavelength band filters CFBz. In an embodiment, the elements in the middle and center pixel regions Y and X may be provided to have substantially the same features.

The microlenses MLBx on the center first wavelength band filter CFBx of the center color filter group in the center pixel region X may have a diameter that is larger than that of the microlenses MLBz corresponding to the edge first wavelength band filter CFBz of the edge color filter group in the edge pixel region Z. A diameter of the microlenses MLGx on the center second wavelength band filter CFGx may be larger than a diameter of the microlenses MLGz on the edge second wavelength band filter CFGz. A diameter of the microlens MLRx on the center third wavelength band filter CFRx may be larger than a diameter of the microlens MLRz on the edge third wavelength band filter CFRz.

In an embodiment, diameters of the microlenses MLRx corresponding to the center third wavelength band filter CFRx of the center color filter group in the center pixel region X may be smaller than diameters of the microlenses MLBz corresponding to the edge first wavelength band filter CFBz of the edge color filter group in the edge pixel region Z. In the center color filter group of the center pixel region X, the middle color filter group of the middle pixel region Y, and the edge color filter group of the edge pixel region Z, the first wavelength band filters CFBx, CFBy, and CFBz may be configured to pass light whose wavelength is shorter than those by the second wavelength band filters CFGx, CFGy, and CFGz and by the third wavelength band filters CFRx, CFRy, and CFRz. The second wavelength band filters CFGx, CFGy, and CFGz may be configured to pass light whose wavelength is shorter than the third wavelength band filters CFRx, CFRy, and CFRz.

According to an embodiment of the inventive concept, in the image sensor 300, the microlenses covering the center pixel region X, the middle pixel region Y, and the edge pixel region Z may be provided to have different diameters from each other. In the same pixel region, the microlenses may have different diameters from each other, depending on the color of the corresponding color filter. Thus, it may be possible to minimize a signal difference between the pixels.

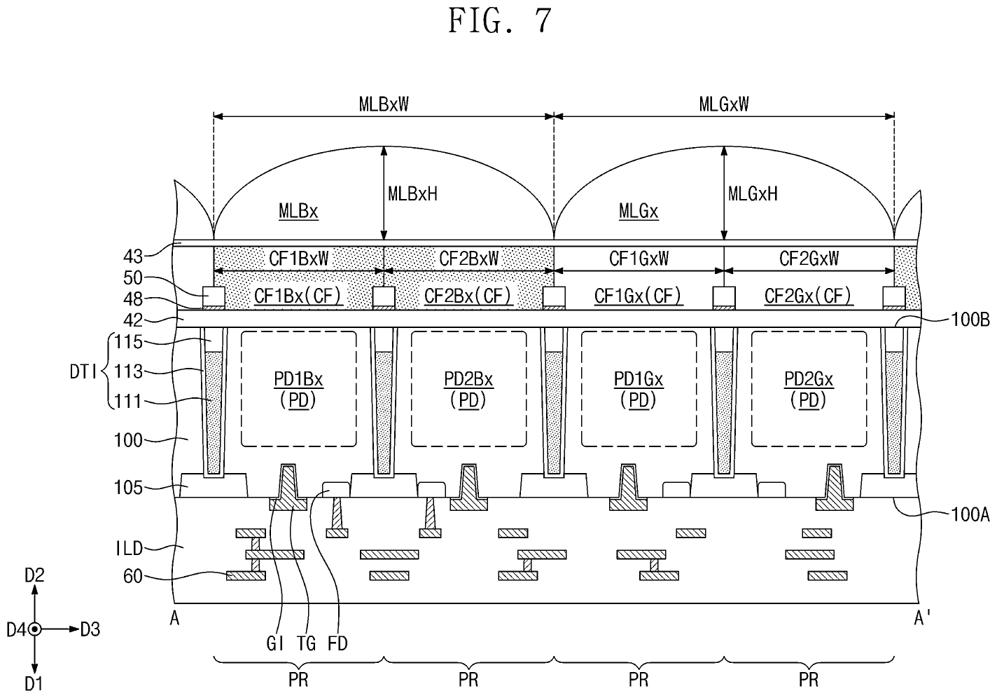

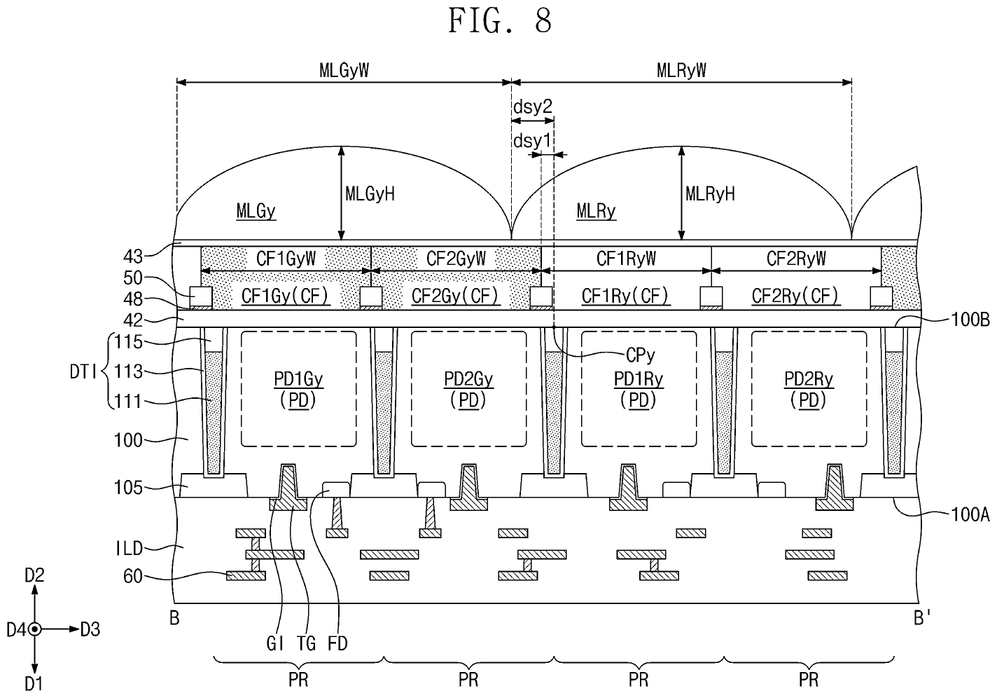

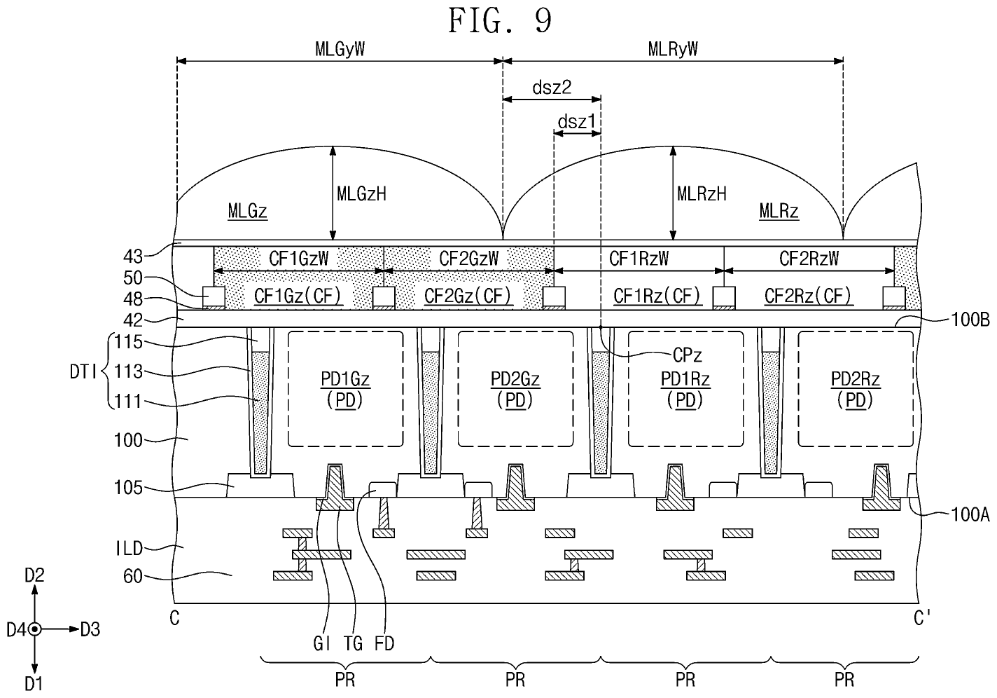

FIG. 7 is a sectional view taken along the line A-A′ of FIG. 3B to illustrate an image sensor 300 according to another embodiment of the inventive concept. FIG. 8 is a sectional view taken along the line B-B′ of FIG. 3B to illustrate an image sensor 300 according to another embodiment of the inventive concept. FIG. 9 is a sectional view taken along the line C-C′ of FIG. 3B to illustrate an image sensor 300 according to another embodiment of the inventive concept. For concise description, a previously-described element may be identified by the same reference number without repeating an overlapping description thereof.

Referring to FIGS. 3 and 7 to 9, the image sensor 300 in the center pixel region X, the middle pixel region Y, the edge pixel region Z according to an embodiment of the inventive concept is illustrated. The deep device isolation pattern DTI may have a lower width near the first surface 100A of the substrate 100. The deep device isolation pattern DTI may have an upper width at a level of the second surface 100B of the substrate 100. The lower width may be smaller than the upper width. That is, the width of the deep device isolation pattern DTI may gradually increase as a distance from the first surface 100A of the substrate 100 increases in a direction toward the second surface 100B. The device isolation layer 105 may be provided between the deep device isolation pattern DTI and the first surface 100A of the substrate 100.

Similar to the embodiments described with reference to FIGS. 4 to 6, the color filter groups may be shifted in the middle and edge pixel regions Y and Z. The microlenses may be shifted in the middle and edge pixel regions Y and Z. The shifting distances of the color filter groups and the microlenses may be larger in the edge pixel region Z than in the middle pixel region Y.

According to an embodiment of the inventive concept, an image sensor may include a center pixel region, a middle pixel region, and an edge pixel region. Microlenses covering the center, middle, and edge pixel regions may have different diameters from each other, and the microlenses covering them may be provided to have different diameters from each other, depending on the kind of a color filter group in each pixel region. It may be possible to minimize a signal difference between pixels sharing the same color filter.

According to an embodiment of the inventive concept, a shifting distance of each of the microlenses may increase as a distance to the edge pixel region reduces. In this case, it may be possible to increase the light-reflection efficiency and improve the sensitivity of the image sensor.

While example embodiments of the inventive concept have been particularly shown and described, it will be understood by one of ordinary skill in the art that variations in form and detail may be made therein without departing from the spirit and scope of the attached claims.

What is claimed is:

1. An image sensor, comprising:
a semiconductor substrate comprising a pixel array region, which has a first pixel region, a second pixel region surrounding the first pixel region, and a third pixel region surrounding the second pixel region;
a plurality of color filter groups provided on the pixel array region, each of the plurality of color filter groups comprising a plurality of color filters; and
a plurality of microlenses provided on the plurality of color filter groups, respectively,
wherein the plurality of color filter groups comprise a first color filter group on the first pixel region, a second color filter group on the second pixel region, and a third color filter group on the third pixel region,
wherein the first color filter group comprises a first first wavelength band filter configured to pass light of a first wavelength band and a second first wavelength band filter configured to pass light of a second wavelength band different from the first wavelength band,
wherein the third color filter group comprises a first third wavelength band filter configured to pass light having a wavelength within the first wavelength band,
wherein, in the first color filter group, a first diameter of a first microlens, among the plurality of microlenses, on the first first wavelength band filter is different from a second diameter of a second microlens, among the plurality of microlenses, on the second first wavelength band filter,
wherein the first diameter of the first microlens on the first first wavelength band filter of the first color filter group is larger than a third diameter of a third microlens, among the plurality of microlenses, on the first third wavelength band filter of the third color filter group, and
wherein the plurality of microlenses are overlaps at least four of the plurality of color filters.

2. The image sensor of claim 1, further comprising:
a plurality of photoelectric conversion parts corresponding to the plurality of color filters, respectively; and
a plurality of deep device isolation patterns defining the plurality of photoelectric conversion parts, the plurality of deep device isolation patterns comprising a first deep device isolation pattern provided between first adjacent photoelectric conversion parts, among the plurality of photoelectric conversion parts, and a second deep device isolation pattern provided between second adjacent photoelectric conversion parts, among the plurality of photoelectric conversion parts,
wherein, in the first pixel region, a first boundary between two first color filters, among the plurality of color filters, corresponding to the first adjacent photoelectric conversion parts overlaps the first deep device isolation pattern,
wherein, in the second pixel region, a second boundary between two second color filters, among the plurality of color filters, corresponding to the second adjacent photoelectric conversion parts does not overlap the second deep device isolation pattern.

3. The image sensor of claim 2, wherein, in the third pixel region, a distance from a third deep device isolation pattern, among the plurality of deep device isolation patterns, to a side surface of a color filter corresponding to the third deep device isolation pattern is defined as a first color filter shift distance,
in the second pixel region, a distance from the second deep device isolation pattern to a side surface of a color filter corresponding to the second deep device isolation pattern is defined as a second color filter shift distance, and
the first color filter shift distance is larger than the second color filter shift distance.

4. The image sensor of claim 1, wherein the first color filter group further comprises a third first wavelength band filter, which is configured to pass light in a wavelength band different from the first first wavelength band filter and the second first wavelength band filter, and
in the first color filter group, a microlens, among the plurality of microlenses, on the third first wavelength band filter has a size different from a second microlens, among the plurality of microlenses, on the second first wavelength band filter.

5. The image sensor of claim 4, wherein, in the first color filter group, the second first wavelength band filter comprises a plurality of second first wavelength band filters,
wherein the second first wavelength band filter is configured pass light having a wavelength smaller than the third first wavelength band filter, and
wherein a plurality of first microlenses, among the plurality of microlenses, on the third first wavelength band filter have diameters that are smaller than a plurality of second microlenses, among the plurality of microlenses, on the second first wavelength band filter.

6. The image sensor of claim 1, further comprising:
a plurality of photoelectric conversion parts corresponding to the color filters, respectively; and
a plurality of deep device isolation patterns defining the plurality of photoelectric conversion parts, the plurality of deep device isolation patterns comprising a first deep device isolation pattern and a second deep device isolation pattern,
wherein in the third pixel region, a distance from the first deep device isolation pattern to an outermost portion of a first microlens, among the plurality of microlenses, corresponding to the first deep device isolation pattern is defined as a first lens shift distance,
in the second pixel region, a distance from the second deep device isolation pattern to an outermost portion of a second microlens, among the plurality of microlenses, corresponding to the second deep device isolation pattern is defined as a second lens shift distance, and
the first lens shift distance is larger than the second lens shift distance.

7. The image sensor of claim 1, wherein the third color filter group comprises a second third wavelength band filter configured to pass light in a wavelength band different from the first third wavelength band filter, and
the second diameter of the second microlens on the second first wavelength band filter is larger than a diameter of a fourth microlens, among the plurality of microlenses, on the second third wavelength band filter.

8. The image sensor of claim 1, further comprising:
a plurality of photoelectric conversion parts corresponding to the color filters, respectively; and
a deep device isolation pattern defining the plurality of photoelectric conversion parts,
wherein a first lens shift distance of a plurality of first microlenses, among the plurality of microlenses, in the third pixel region is larger than a second lens shift distance of a plurality of second microlenses, among the plurality of microlenses, in the second pixel region.

9. An image sensor, comprising:
a semiconductor substrate comprising a pixel array region, which has a first pixel region, a second pixel region surrounding the first pixel region, and a third pixel region surrounding the second pixel region;
a plurality of color filter groups provided on the pixel array region, each of the plurality of color filter groups comprising a plurality of color filters;
a plurality of photoelectric conversion parts corresponding to the color filters, respectively; and
a plurality of microlenses provided on the plurality of color filter groups, respectively,
wherein each of the plurality of microlenses corresponds to four of the plurality of photoelectric conversion parts,
wherein the plurality of color filter groups comprises a first color filter group on the first pixel region, a second color filter group on the second pixel region, and a third color filter group on the third pixel region,
wherein each of the first color filter group, the second color filter group, and the third color filter group comprises a first wavelength band filter, a second wavelength band filter, and a third wavelength band filter, which are configured to pass light having wavelengths in different wavelength bands,
wherein a diameter of a first microlens, among the plurality of microlenses, on the first wavelength band filter of the first color filter group is larger than a diameter of a second microlens, among the plurality of microlenses, on the first wavelength band filter of the third color filter group, and
wherein in the third color filter group, a diameter of a third microlens, among the plurality of microlenses, corresponding to the first wavelength band filter is different from a diameter of a fourth microlens, among the plurality of microlenses, corresponding to the second wavelength band filter.

10. The image sensor of claim 9, wherein, in the third color filter group, the first wavelength band filter is configured to pass light having a wavelength that is smaller than the third wavelength band filter, and
a diameter of the third microlens corresponding to the first wavelength band filter is larger than a diameter of a first microlens, among the plurality of microlenses, corresponding to the third wavelength band filter.

11. The image sensor of claim 9, wherein, in the first color filter group and the third color filter group, the first wavelength band filter is configured to pass light having a wavelength is shorter than the second wavelength band filter and third wavelength band filter, and
a diameter of the third microlens corresponding to the first wavelength band filter of the third color filter group is larger than a diameter of a sixth microlens, among the plurality of microlenses, corresponding to the third wavelength band filter of the first color filter group.

12. The image sensor of claim 9, further comprising a deep device isolation pattern, which is provided in the pixel array region of the semiconductor substrate to define a plurality of pixel regions.

13. The image sensor of claim 12, wherein, in the third pixel region, the deep device isolation pattern is not overlapped with an outermost portion of the plurality of microlenses.

14. The image sensor of claim 9, wherein a shift distance of each of a plurality of first color filters, among the plurality of color filters, in the third pixel region is larger than a shift distance of each of a plurality of second color filters, among the plurality of color filters in the second pixel region.

15. The image sensor of claim 9, wherein at least two of the plurality of microlenses on the third color filter group have different diameters from each other, and
at least two of the plurality of microlenses on the third color filter group have a same height.

16. The image sensor of claim 9, further comprising a deep device isolation pattern, which is provided in the pixel array region of the semiconductor substrate to define a plurality of pixel regions,
wherein the semiconductor substrate comprises a first surface and a second surface, which are opposite to each other,
wherein the plurality of color filter groups are provided on the second surface, and
a width of the deep device isolation pattern decreases as a distance from the first surface increases in a direction toward the second surface.

17. The image sensor of claim 9, further comprising a deep device isolation pattern, which is provided in the pixel array region of the semiconductor substrate to define a plurality of pixel regions,
wherein the semiconductor substrate comprises a first surface and a second surface, which are opposite to each other,
wherein the plurality of color filter groups are provided on the second surface, and
a width of the deep device isolation pattern increases as a distance from the first surface increases in a direction toward the second surface.

18. The image sensor of claim 9, wherein each of the plurality of color pixel groups comprises a first color filter, a second color filter, a third color filter and a fourth color filter arranged in two rows and two columns, and
wherein the first color filter, the second color filter, the third color filter and the fourth color filter have a color filter of a same color.

19. An image sensor, comprising:
a semiconductor substrate comprising a light-receiving region, a light-blocking region, and a pad region, the semiconductor substrate having a first surface and a second surface, which are opposite to each other;
a deep device isolation pattern provided in the light-receiving region and the light-blocking region of the semiconductor substrate to define pixel regions;
a plurality of photoelectric conversion regions provided in the light-receiving region and the light-blocking region of the semiconductor substrate;
a plurality of color filter groups provided on the second surface, each of the color filter groups comprising a first color filter, a second color filter, a third color filter and a fourth color filter arranged in two rows and two columns;
a transfer gate on the first surface;
a pixel circuit layer on the first surface; and
a plurality of microlenses provided on the plurality of color filter groups, respectively,
wherein one of the microlenses overlaps with the first color filter, the second color filter, the third color filter and the fourth color filter,
wherein the light-receiving region comprises:
a first pixel region,
a second pixel region surrounding the first pixel region; and
a third pixel region surrounding the second pixel region,
wherein the plurality of color filter groups comprises:
a first color filter group on the first pixel region;
a second color filter group on the second pixel region; and
a third color filter group on the third pixel region,
wherein the first color filter group comprises a first first wavelength band filter and a second first wavelength band filter, which are configured to pass light in different wavelength bands from each other,
wherein the third color filter group comprises a first third wavelength band filter, which is configured to pass light in a same wavelength band as the first first wavelength band filter,
wherein, in the first color filter group, a diameter of a first microlens, among the plurality of microlenses, on the first first wavelength band filter is larger than a diameter of a second microlens, among the plurality of microlenses, on the second first wavelength band filter, and
wherein a plurality of third microlenses on the first first wavelength band filter of the first color filter group, among the plurality of microlenses, have diameters that are larger than a plurality of fourth microlenses on the first third wavelength band filter of the third color filter group, among the plurality of microlenses.

20. The image sensor of claim 19, wherein the third color filter group comprises a second third wavelength band filter configured to pass light in a wavelength band different from the first third wavelength band, and
a diameter of the second microlens corresponding to the second first wavelength band filter is larger than a diameter of a fifth microlens corresponding to the second third wavelength band filter, among the plurality of microlenses.
